(19) United States
(12) Patent Application Publication
(10) Pub. No.: US 2026/0032845 A1
(43) Pub. Date: Jan. 29, 2026

(54) SUPPORT DEVICE FOR MOUNTING ELECTRONIC EQUIPMENT

(71) Applicant: LITE-ON TECHNOLOGY CORPORATION, Taipei (TW)

(72) Inventors: Cheng-Hsuen Chien, Taipei (TW); Wei-Ming Shieh, Taipei (TW); Hsiao-Ming Chen, Taipei (TW)

(21) Appl. No.: 19/007,089

(22) Filed: Dec. 31, 2024

Related U.S. Application Data
(60) Provisional application No. 63/674,326, filed on Jul. 23, 2024.

(30) Foreign Application Priority Data
Oct. 30, 2024 (CN) 202422635396.9

(51) Int. Cl. H05K 7/14; H05K 5/02; H05K 9/00

(52) U.S. Cl. CPC H05K 7/1425; H05K 5/0221; H05K 5/023; H05K 7/1418; H05K 9/0037

(57) ABSTRACT

A support device for mounting electronic equipment is provided. The support device includes a panel assembly, an electromagnetic shielding assembly, a housing assembly disposed between the panel assembly and the electromagnetic shielding assembly, and a bracket assembly. The electromagnetic shielding assembly is disposed between the housing assembly and the bracket assembly. The bracket assembly includes an extension structure extending toward the housing assembly and at least partially disposed within the housing assembly.

This application claims the benefit of U.S. provisional application Ser. No. 63/674,326, filed Jul. 23, 2024, and People's Republic of China application Serial No. 202422635396.9, filed Oct. 30, 2024, the subject matters of which are incorporated herein by reference.

### BACKGROUND

### Technical Field

The present disclosure relates to a support device, and more particularly to a support device for mounting electronic equipment.

### Description of the Related Art

Cage can be used to accommodate one or more electronic equipment. In order to facilitate check, maintenance or replacement of electronic equipment in the cage, the electronic equipment is usually mounted on a support device, so that the electronic equipment can be installed in the cage through the support device. The conventional support device is composed of a large number of elements, resulting in high manufacturing cost and making it unsuitable for automated assembly, which causes a lot of inconvenience and does not meet the needs.

### SUMMARY

The present disclosure provides a support device for mounting electronic equipment, which is suitable for automated assembly, can be manufactured at low cost and can improve the aforementioned problems in the existing technology.

According to some embodiments, a support device for mounting electronic equipment is provided. The support device includes a panel assembly, an electromagnetic shielding assembly, a housing assembly disposed between the panel assembly and the electromagnetic shielding assembly, and a bracket assembly. The electromagnetic shielding assembly is disposed between the housing assembly and the bracket assembly. The bracket assembly includes an extension structure extending toward the housing assembly and at least partially disposed within the housing assembly.

The above and other embodiments of the disclosure will become better understood with regard to the following detailed description of the non-limiting embodiment(s). The following description is made with reference to the accompanying drawings.

### BRIEF DESCRIPTION OF THE DRAWINGS

FIG. 1 illustrates a schematic view of a support device according to the first embodiment of the present disclosure.

FIG. 2 illustrates a schematic view of the support device according to the first embodiment of the present disclosure.

FIG. 3A illustrates a schematic exploded view of the support device according to the first embodiment of the present disclosure.

FIG. 3B illustrates a schematic exploded view of the support device according to the first embodiment of the present disclosure.

FIG. 4 illustrates a partial perspective view of the support device according to the first embodiment of the present disclosure.

FIG. 5 illustrates a schematic view of a support device according to the second embodiment of the present disclosure.

FIG. 6 illustrates a schematic view of a support device according to the third embodiment of the present disclosure.

FIG. 7 illustrates a schematic view of the support device according to the third embodiment of the present disclosure.

FIG. 8A illustrates a schematic exploded view of the support device according to the third embodiment of the present disclosure.

FIG. 8B illustrates a schematic exploded view of the support device according to the third embodiment of the present disclosure.

FIG. 9 illustrates a partial perspective view of the support device according to the third embodiment of the present disclosure.

FIG. 10 illustrates a schematic view of a support device according to the fourth embodiment of the present disclosure.

### DETAILED DESCRIPTION

Various embodiments will be described more fully hereinafter with reference to accompanying drawings. For clarity, the elements may not be drawn to scale. The specification and the drawings are to be regarded as an illustrative sense rather than a restrictive sense. The illustration uses the same/similar reference numerals to indicate the same/similar elements. Moreover, use of ordinal terms such as “first”, “second”, “third”, etc., in the specification and claims to modify an element does not by itself imply any priority, precedence, or order of one claim element over another, but are used merely as labels to distinguish one claim element having a certain name from another element having the same name (but for use of the ordinal term) to distinguish the claim elements.

As used in the specification and the appended claims, spatial relation terms such as “on”, “above”, “over”, “upper,” “top”, “below”, “beneath”, “under”, “lower” and “bottom” be used to describe the relative spatial relations or positional relations between one element(s) and another element(s) as illustrated in the drawings, and these spatial relations or positional relations, unless specified otherwise, can be direct or indirect. The spatial relation terms are intended to encompass different orientations of structures in addition to the orientation depicted in the drawings. The structure can be inverted or rotated by various angles, and the spatial relation descriptions used herein can be interpreted accordingly. As used in the specification and the appended claims, the singular forms “a,” “an,” and “the” are intended to include the plural forms as well, unless the context clearly indicates otherwise. As used in the specification and the appended claims, the term “and/or” includes any and all combinations of one or more of the associated listed items.

The present disclosure provides embodiments of support devices. The support device can be used to mount electronic equipment, such as a server or a data storage device. The data storage device can be a hard disk drive (HDD) or a solid-state drive (SSD). The electronic equipment can be mounted (e.g. fastened) on the support device, and the support device is detachably installed in the cage, and thus the electronic equipment together with the support device can be detachably installed in the cage. In some embodiments, the support device according to the present disclosure can be used to mount E1.S solid-state drives based on EDSFF.

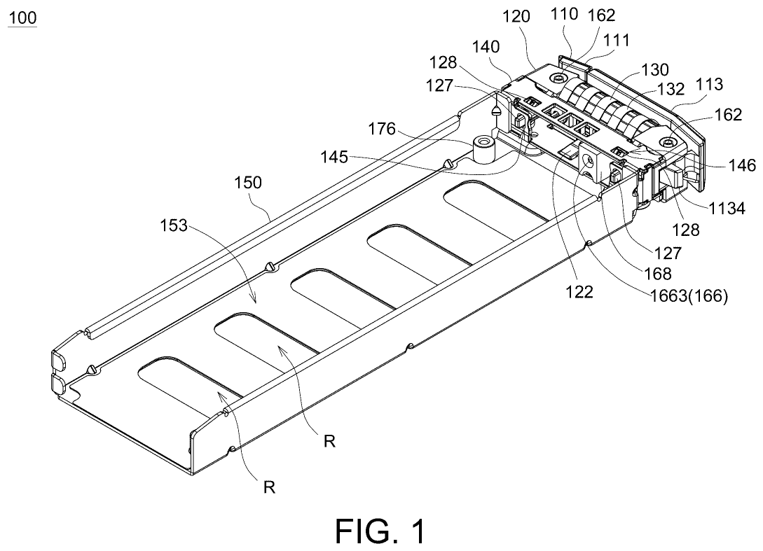

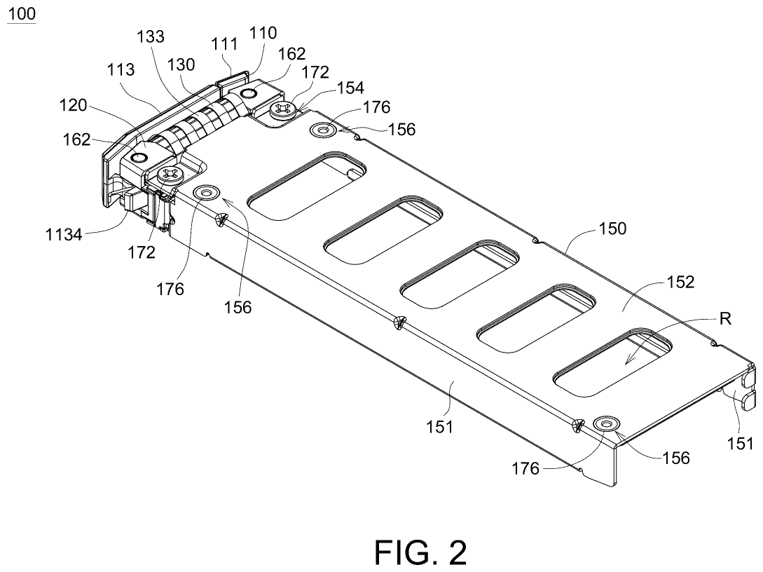

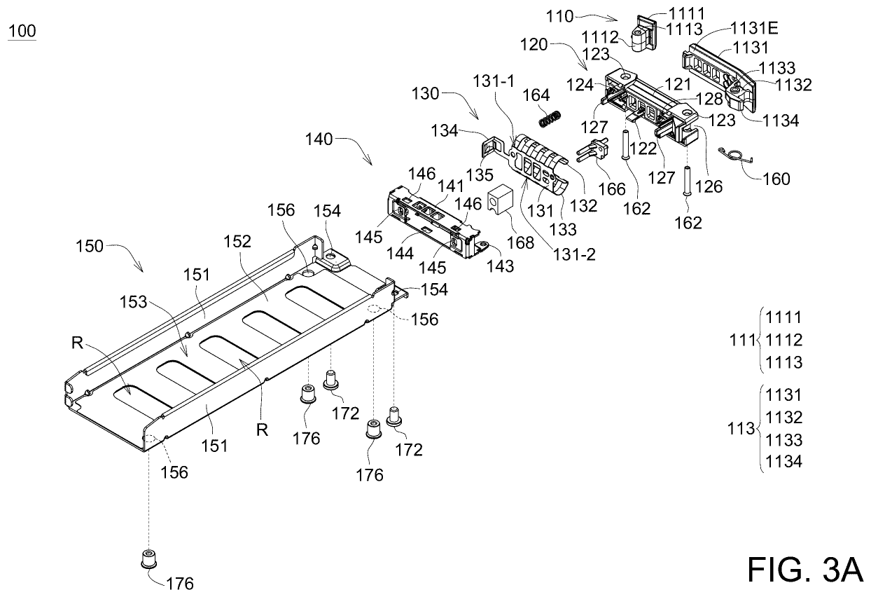

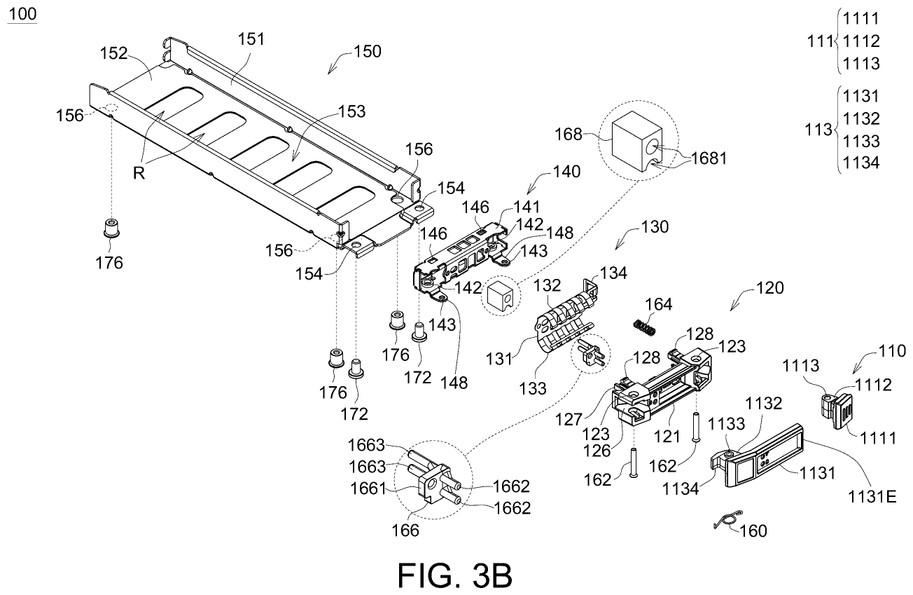

Referring to FIG. 1 to FIG. 4, FIG. 1 illustrates a schematic view of a support device 100 according to the first embodiment of the present disclosure, FIG. 2 illustrates a schematic view of the support device 100 according to the first embodiment of the present disclosure with different directions of viewing, FIG. 3A and FIG. 3B illustrate schematic exploded views of the support device 100 according to the first embodiment of the present disclosure, and FIG. 4 illustrates a partial perspective view of the support device 100 according to the first embodiment of the present disclosure. The support device 100 includes a panel assembly 110, an electromagnetic shielding assembly 130, a housing assembly 120 and a bracket assembly 140. The housing assembly 120 is disposed between the panel assembly 110 and the electromagnetic shielding assembly 130. The electromagnetic shielding assembly 130 is disposed between the housing assembly 120 and the bracket assembly 140. As shown in FIG. 2 and FIG. 3B, the bracket assembly 140 includes an extension structure 148 extending toward the housing assembly 120 and at least partially disposed within the housing assembly 120.

The panel assembly 110 includes a button 111 and a handle 113. The button 111 abuts a handle movable end 1131E of the handle 113. The button 111 includes a button body 1111, a button bulge part 1112 and a button hole 1113. The button bulge part 1112 is disposed on the inner surface of the button body 1111 and protrudes from the inner surface of the button body 1111, and the inner surface of the button body 1111 faces the housing assembly 120. The button hole 1113 extends along a direction parallel to the inner surface of the button body 1111 (or can be understood as a longitudinal direction) and penetrates the button bulge part 1112. The handle 113 includes a handle body 1131, a handle bulge part 1132, a handle hole 1133 and a handle hook part 1134. The handle bulge part 1132 is disposed on the inner surface of the handle body 1131 and protrudes from the inner surface of the handle body 1131, and the inner surface of the handle body 1131 faces the housing assembly 120. The handle hole 1133 extends along a direction parallel to the inner surface of the handle body 1131 (or can be understood as a longitudinal direction) and penetrates the handle bulge part 1132. The handle hook part 1134 is disposed on the handle bulge part 1132 and extends toward the outside of the support device 100. When the support device 100 is installed in a cage, the handle hook part 1134 can be engaged with a corresponding coupling structure in the cage to increase the connection stability between the support device 100 and the cage. The panel assembly 110 may be made of a polymer material, such as polycarbonate (PC), acrylonitrile butadiene styrene (ABS) or a combination thereof.

The housing assembly 120 includes a housing body 121, housing through holes 123, a recess 124, a channel 126, housing bulge parts 127, first snap portions 128 and a second snap portion 122. The housing through holes 123 can be disposed on opposite sides of the housing body 121. The housing through holes 123 may extend along the longitudinal direction and penetrate the housing body 121. The first snap portions 128 may extend toward the electromagnetic shielding assembly 130. The first snap portions 128 can be disposed on the housing body 121. The first snap portions 128 can be disposed close to the upper surface (or first surface) of the housing body 121. The second snap portion 122 can be disposed on the housing body 121. The second snap portion 122 may extend toward the electromagnetic shielding assembly 130. The second snap portion 122 may be disposed between the first snap portions 128. The second snap portion 122 may be disposed between the housing bulge parts 127. The second snap portion 122 can be disposed close to the lower surface (or second surface) of the housing body 121. The housing bulge parts 127 may extend toward the electromagnetic shielding assembly 130. The housing bulge parts 127 can be disposed on the housing body 121. The housing bulge parts 127 can be disposed on opposite sides of the housing body 121. The housing bulge parts 127 may be below the first snap portions 128. The recess 124 is disposed in the housing body 121. The recess 124 has an opening toward the electromagnetic shielding assembly 130. The channel 126 can be disposed in the housing body 121 and has an opening toward the panel assembly 110 and the outside of the support device 100. The channel 126 is used to accommodate at least a portion of the handle bulge part 1132 and a portion of the handle hook part 1134 (as shown in FIG. 4), and another portion of the handle hook part 1134 protrudes from a side surface of the support device 100 to be engaged with a corresponding coupling structure in the cage. The channel 126 can communicate with one of the housing through holes 123. As shown in FIG. 1, the panel assembly 110 covers a side surface of the housing body 121. The housing assembly 120 may be made of a polymer material, such as polycarbonate (PC), acrylonitrile butadiene styrene (ABS) or a combination thereof.

The electromagnetic shielding assembly 130 includes a body 131, a first elastic piece 132, a second elastic piece 133, an extended portion 134 and an elastic structure 135. The body 131 is disposed between the first elastic piece 132 and the second elastic piece 133. The first elastic piece 132 can be disposed on or connected to a first side 131-1 of the body 131. The second elastic piece 133 can be disposed on or connected to a second side 131-2 of the body 131. The first side 131-1 of the body 131 is opposite to the second side 131-2 of the body 131. The first elastic piece 132 extends from the first side 131-1 of the body 131 toward the second elastic piece 133. The second elastic piece 133 extends from the second side 131-2 of the body 131 toward the first elastic piece 132. The first elastic piece 132 may not contact the second elastic piece 133. The body 131, the first elastic piece 132 and the second elastic piece 133 can define a space for accommodating the housing assembly 120. The first elastic piece 132 can cover a portion of the upper surface (or first surface) of the housing assembly 120 (as shown in FIG. 1). The second elastic piece 133 can cover a portion of the lower surface (or second surface) of the housing assembly 120 (as shown in FIG. 2). The extended portion 134 can be connected to the body 131. The extended portion 134 can extend from a side of the body 131 toward the outside of the support device 100. In the present embodiment, the extended portion 134 has an L-shaped bending structure, but the present disclosure is not limited thereto. The elastic structure 135 is disposed on the extended portion 134. In the present embodiment, the elastic structure 135 can be disposed on an arm of the L-shaped bending structure of the extended portion 134. The elastic structure 135 may have a curved structure and protrude toward the outside of the support device 100. When the support device 100 is installed in the cage, the elastic structure 135 can be positioned in a corresponding accommodating hole of the cage to increase the connection stability between the support device 100 and the cage. The electromagnetic shielding assembly 130 may be made of a conductive material, such as SUS301 stainless steel. In an embodiment, the elastic structure 135 can contact the cage for electrostatic discharge, which can improve the electrostatic protection capability of the support device 100.

The bracket assembly 140 includes a bracket body 141, bracket through holes 142, first connection holes 143, openings 145, extension structures 148, first snap holes 146 and a second snap hole 144. The first snap holes 146 can be disposed on opposite sides of the bracket body 141. The first snap holes 146 can be disposed on and penetrate the upper surface (or first surface) of the bracket body 141. The bracket through holes 142 can be disposed on opposite sides of the bracket body 141. The bracket through holes 142 can penetrate the lower surface (or second surface) of the bracket body 141, as shown in FIG. 3B. The extension structures 148 can be disposed on the edge of the lower surface of the bracket body 141. The first connection holes 143 can penetrate the extension structures 148 respectively. The extension structures 148 can be separated from each other. The openings 145 can be disposed on opposite sides of the bracket body 141. The openings 145 may penetrate a side surface of the bracket body 141, and the side surface is connected between the first surface and the second surface of the bracket body 141. The housing bulge part 127 of the housing assembly 120 can pass through the opening 145 of the bracket assembly 140, as shown in FIG. 1. The second snap hole 144 can be disposed on and penetrate the lower surface (or second surface) of the bracket body 141 of the bracket assembly 140, as shown in FIG. 3A. The second snap hole 144 can be disposed between the first snap holes 146. The second snap hole 144 can be disposed between the bracket through holes 142. The second snap portion 122 of the housing assembly 120 can pass through the electromagnetic shielding assembly 130 and is engaged with the second snap hole 144 of the bracket assembly 140. The first snap portion 128 of the housing assembly 120 can be engaged with the first snap hole 146 of the bracket assembly 140. The housing assembly 120 can be attached or fixed to the bracket assembly 140 through the second snap portion 122 and the first snap portion 128. A portion of the extended portion 134 of the electromagnetic shielding assembly 130 can be disposed in the bracket assembly 140, and the elastic structure 135 can pass through the bracket assembly 140 from a side surface of the bracket assembly 140 and protrude from the side surface of the bracket assembly 140. The bracket assembly 140 may be made of a metal material, such as SGCC steel.

The electromagnetic shielding assembly 130, the bracket assembly 140 and the electronic equipment mounted on the support device 100 can form a conductive path for electrostatic discharge, grounding, etc., which can effectively increase the electromagnetic interference (EMI) protection.

The support device 100 may further include positioning pins 162. At least a portion of the extension structure 148 is disposed in the housing assembly 120 so that the first connection hole 143 overlaps the housing through hole 123 of the housing assembly 120. At least a portion of the button bulge part 1112 is disposed in the housing assembly 120 so that the button hole 1113 overlaps one of the housing through holes 123 of the housing assembly 120. At least a portion of the handle bulge part 1132 is disposed in the channel 126 of the housing assembly 120 so that the handle hole 1133 overlaps another one of the housing through holes 123 of the housing assembly 120. One of the positioning pins 162 can pass through the button hole 1113, the housing through hole 123 and the first connection hole 143 which overlap with each other, such that the button 111 can be pivotally connected to the housing assembly 120 through this positioning pin 162, and the button 111 can rotate relative to the housing assembly 120 with this positioning pin 162 as a rotation axis. Another one of the positioning pins 162 can pass through the handle hole 1133, the housing through holes 123 and the first connection hole 143 which overlap with each other, such that the handle 113 can be pivotally connected to the housing assembly 120 through this positioning pin 162, and the handle 113 can rotate relative to the housing assembly 120 with this positioning pin 162 as a rotation axis. The housing assembly 120 can be attached to the bracket assembly 140 through the positioning pins 162.

The support device 100 may further include a first elastic element 160, a second elastic element 164, a latch 166 and a buffer 168. The first elastic element 160 is disposed on one side of the handle bulge part 1132 of the handle 113. The first elastic element 160 can be disposed below the handle bulge part 1132 of the handle 113. A portion of the first elastic element 160 is disposed in the channel 126 of the housing assembly 120, and another portion of the first elastic element 160 is outside the channel 126 and protrudes from a side surface of the support device 100 (as shown in FIG. 4). The first elastic element 160 and the handle hook part 1134 can protrude from the same side surface of the support device 100. The first elastic element 160 is sleeved on the positioning pin 162 passing through the handle hole 1133. For example, the first elastic element 160 is a torsion spring.

Rotating the button 111 relative to the housing assembly 120 with this positioning pin 162 as a rotation axis can release the button 111 from the handle 113; at this time, the torsion provided by the first elastic element 160 pushes the handle movable end 1131E of the handle 113 away from the housing assembly 120. Then, the user can apply force on the handle movable end 1131E of the handle 113 to further rotate the handle 113 relative to the housing assembly 120 with the positioning pin 162 as a rotation axis, which causes the handle hook part 1134 of the handle 113 to move to disengage the support device 100 from the corresponding coupling structure of the cage; therefore, the support device 100 can be removed from the cage. The torsion provided by the first elastic element 160 can push the handle movable end 1131E of the handle 113 away from the housing assembly 120 even if the user does not exert force on the handle 113, which is conducive to the user holding or pushing the handle 113 for subsequent operations. For example, the button 111 can rotate along the first direction D1 (as shown in FIG. 4) with the positioning pin 162 as a rotation axis to release the handle 113; the handle 113 can rotate along the second direction D2 (as shown in FIG. 4) with the positioning pin 162 as a rotation axis at this time to disengage the support device 100 from the corresponding coupling structure of the cage. The first direction D1 can be different from the second direction D2. In an embodiment, the first direction D1 can be counterclockwise, and the second direction D2 can be clockwise.

A portion of the second elastic element 164 is disposed in the recess 124 of the housing assembly 120, and another portion of the second elastic element 164 passes through the extended portion 134 of the electromagnetic shielding assembly 130 and is disposed in the bracket assembly 140 (as shown in FIG. 4). For example, the second elastic element 164 is a compression spring or a tension spring. The force provided by the second elastic element 164 can cause the button 111 to rotate in the direction opposite to the first direction D1 (as shown in FIG. 4) and return to the position shown in FIGS. 1, 2 and 4. The second elastic element 164 can return to the position shown in FIGS. 1, 2 and 4 without force exerted by the user. The first elastic element 160 may be made of a metal material, such as SUS304 stainless steel. The second elastic element 164 may be made of a metal material, such as steel.

The buffer 168 is disposed in the bracket assembly 140. The buffer 168 includes through holes 1681. In the present embodiment, the through holes 1681 can be arranged along the longitudinal direction; that is, one of the through holes 1681 can be above another one of the through holes 1681. The buffer 168 can shield light. The latch 166 includes first pillars 1662, second pillars 1663 and a connection portion 1661 between the first pillars 1662 and the second pillars 1663. The first pillar 1662 and the second pillar 1663 extend toward different directions. The first pillars 1662 extend from a first surface of the connection portion 1661 toward the panel assembly 110. The first pillars 1662 can be separated from each other. The second pillars 1663 extend from a second surface of the connection portion 1661 toward the bracket assembly 140. The second pillars 1663 can be separated from each other. The first surface of the connection portion 1661 is opposite to the second surface of the connection portion 1661. As shown in FIG. 4, a portion of the latch 166 is disposed in the housing assembly 120, and another portion of the latch 166 passes through the electromagnetic shielding assembly 130 and is disposed in the buffer 168. As shown in FIG. 4, the first pillars 1662 and the connection portion 1661 of the latch 166 are disposed in the housing assembly 120, the second surface of the latch 166 can contact or abut the body 131 of the electromagnetic shielding assembly 130, and the second pillars 1663 of the latch 166 pass through the electromagnetic shielding assembly 130 and is disposed in the buffer 168. The second pillar 1663 of the latch 166 can be disposed in the through hole 1681 of the buffer 168. For example, the position of the through holes 1681 of the buffer 168 can correspond to the position of the second pillars 1663 of the latch 166, so that the second pillar 1663 of the latch 166 can be inserted into the through hole 1681 of the buffer 168 and disposed in the through hole 1681 of the buffer 168. The latch 166 may be made of a polymer material, such as polycarbonate. The buffer 168 may be made of foam, foam rubber or other materials.

The support device 100 may further include a tray assembly 150, a first fastener 172 and a second fastener 176. The bracket assembly 140 is disposed between the tray assembly 150 and the electromagnetic shielding assembly 130. The tray assembly 150 includes two side plates 151, a bottom plate 152 disposed between the side plates 151, second connection holes 154 and fastening holes 156. Two side plates 151 can be connected to the bottom plate 152. Two side plates 151 and the bottom plate 152 can define an accommodation space 153 for accommodating the electronic equipment (e.g. data storage device). The electronic equipment can be disposed in the accommodation space 153 and can be engaged with the tray assembly 150.

The electronic equipment may contact the bracket assembly 140. In an embodiment, the electronic equipment can be fixed in (or engaged with) the accommodation space 153 of the tray assembly 150 without using fasteners such as screws.

The second connection holes 154 and the fastening holes 156 can penetrate the bottom plate 152. The bracket assembly 140 can be disposed above the bottom plate 152, the bracket through hole 142 of the bracket assembly 140 can overlap the second connection hole 154, the first fastener 172 can pass through the bracket through hole 142 and the second connection hole 154 which overlap with each other, and thus the tray assembly 150 can be fastened to the bracket assembly 140 through the first fastener 172. The second fastener 176 can pass through the fastening hole 156. The tray assembly 150 may have a multi-layer structure (not shown). The tray assembly 150 may be made of a metal material, a polymer material, or a combination thereof. For example, the first fastener 172 is a screw. For example, the second fastener 176 is a standoff.

Optionally, the tray assembly 150 may further include apertures R. The apertures R are disposed on the bottom plate 152 and are separate from each other. The apertures R may penetrate the bottom plate 152.

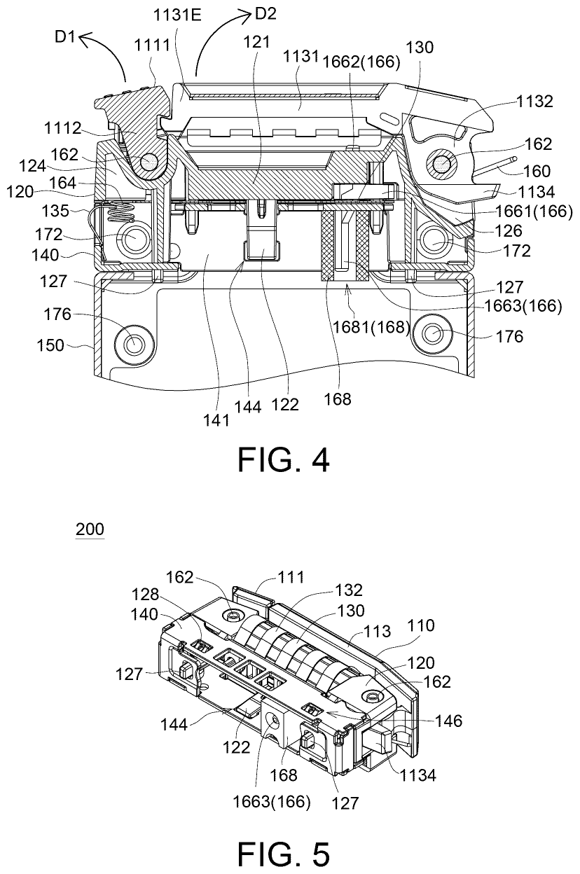

Referring to FIG. 5, FIG. 5 illustrates a schematic view of a support device 200 according to the second embodiment of the present disclosure. The difference between the support device 200 and the support device 100 shown in FIG. 1 to FIG. 4 is that, the support device 200 does not include the tray assembly 150. The support device 200 can be used to mount the electronic equipment having a tray (not shown), and the electronic equipment having a tray can be, for example, a server or a data storage device. The data storage device can be a hard disk drive (HDD) or a solid-state drive (SSD). The support device 200 can be fastened to the tray of the electronic equipment, and the support device 200 can be detachably installed in the cage (not shown). Thus the electronic equipment together with the support device 200 can be detachably installed in the cage.

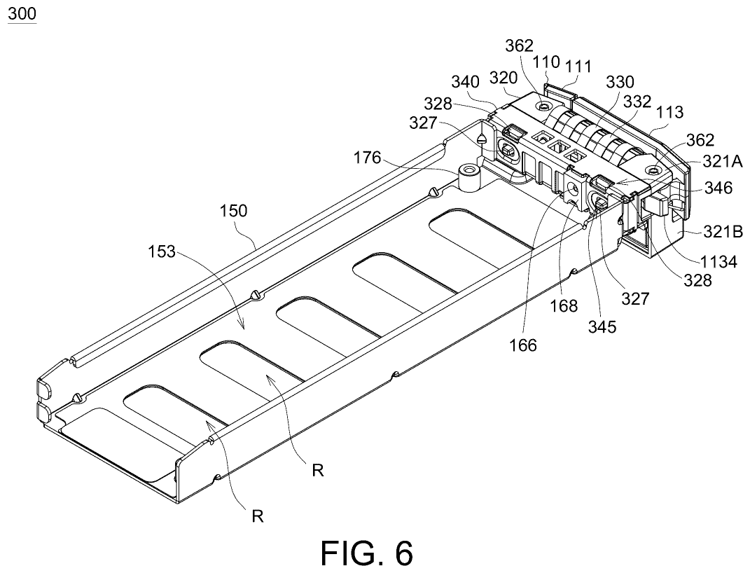

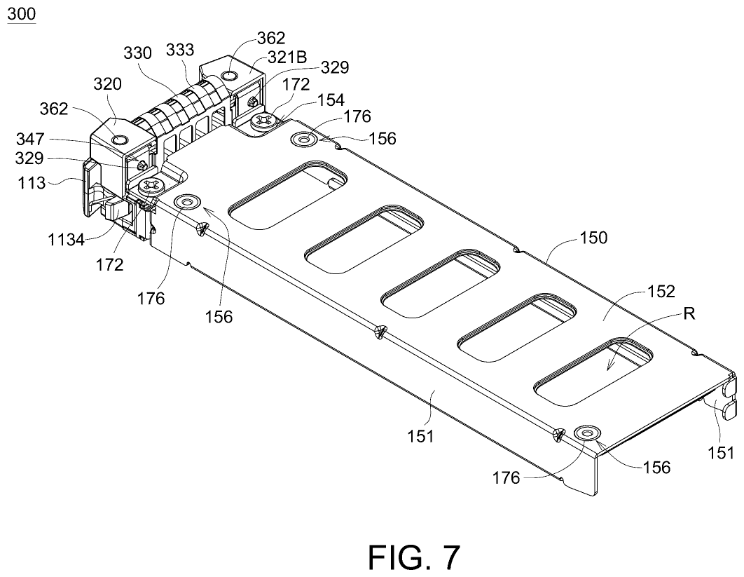

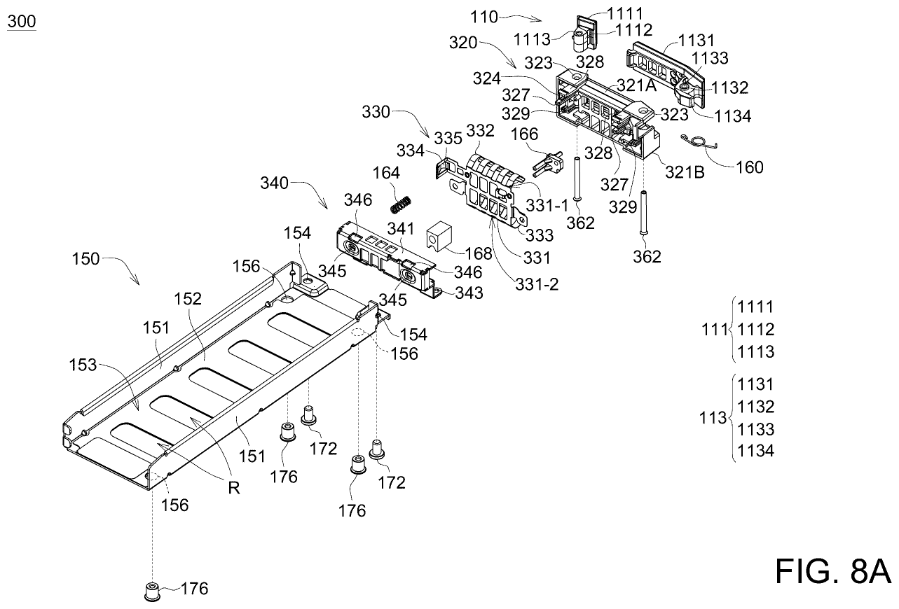

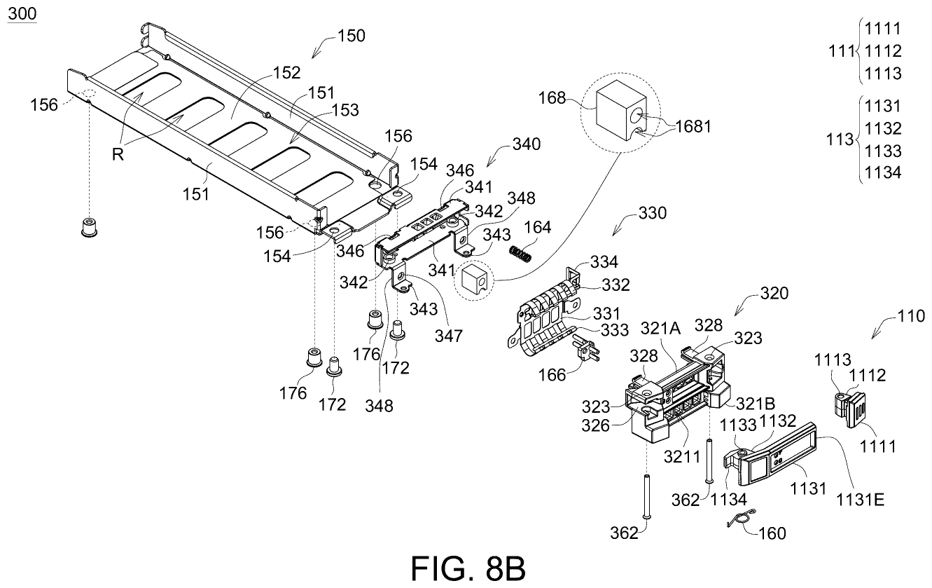

Referring to FIG. 6 to FIG. 9, FIG. 6 illustrates a schematic view of a support device 300 according to the third embodiment of the present disclosure, FIG. 7 illustrates a schematic view of the support device 300 according to the third embodiment of the present disclosure with different directions of viewing, FIG. 8A and FIG. 8B illustrate schematic exploded views of the support device 300 according to the third embodiment of the present disclosure, and FIG. 9 illustrates a partial perspective view of the support device 300 according to the third embodiment of the present disclosure. The differences between the support device 300 and the support device 100 shown in FIG. 1 to FIG. 0.4 are that, the housing assembly 320, the electromagnetic shielding assembly 330 and the bracket assembly 340 can have different structures. In addition, some elements in the third embodiment shown in FIG. 6 to FIG. 9 are the same or similar to some elements in the first embodiment shown in FIG. 1 to FIG. 4; these elements are indicated by the same reference numerals; the descriptions of these elements are shown in the previous paragraphs and will not be repeated here.

The support device 300 includes a panel assembly 110, an electromagnetic shielding assembly 330, a housing assembly 320 and a bracket assembly 340. The housing assembly 320 is disposed between the panel assembly 110 and the electromagnetic shielding assembly 330. The electromagnetic shielding assembly 330 is disposed between the housing assembly 320 and the bracket assembly 340. As shown in FIG. 7 and FIG. 8B, the bracket assembly 340 includes an extension structure 348 extending toward the housing assembly 320 and at least partially disposed within the housing assembly 320.

The height of the housing assembly 320 in the longitudinal direction can be larger than the height of the housing assembly 120 in the longitudinal direction. The housing assembly 320 includes an upper housing body 321A (or first housing body), a lower housing body 321B (or second housing body), housing through holes 323, a recess 324, a channel 326, housing bulge parts 327, first snap portions 328 and housing pillars 329. The lower housing body 321B is disposed on one side of the upper housing body 321A. The lower housing body 321B is disposed under the upper housing body 321A. The lower housing body 321B can be connected to the upper housing body 321A. The housing assembly 320 may further include vent holes 3211 penetrating the lower housing body 321B. The vent holes 3211 can improve the heat dissipation of the support device 300. The housing through holes 323 can be disposed on opposite sides of the upper housing body 321A. The housing through hole 323 can extend along the longitudinal direction and penetrate the upper housing body 321A and the lower housing body 321B. The first snap portions 328 may extend toward the electromagnetic shielding assembly 330. The first snap portions 328 can be disposed on the upper housing body 321A. The first snap portions 328 can be disposed close to the upper surface of the upper housing body 321A. The housing bulge parts 327 may extend toward the electromagnetic shielding assembly 330. The housing bulge parts 327 can be disposed on the upper housing body 321A. The housing bulge parts 327 can be disposed on opposite sides of the upper housing body 321A. The housing bulge parts 327 may be disposed below the first snap portions 328. The recess 324 is disposed in the upper housing body 321A. The recess 324 has an opening toward the electromagnetic shielding assembly 330. The channel 326 can be disposed in the upper housing body 321A and have an opening toward the panel assembly 110 and the outside of the support device 300. The channel 326 is used to accommodate at least a portion of the handle bulge part 1132 and a portion of the handle hook part 1134 (as shown in FIG. 9). The channel 326 can communicate with one of the housing through holes 323. The housing pillars 329 can be disposed on the lower housing body 321B. The housing pillars 329 can be disposed on opposite sides of the lower housing body 321B. The housing pillars 329 can extend toward the electromagnetic shielding assembly 330. The housing pillars 329 can be disposed below the first snap portions 328 and the housing bulge parts 327. The housing assembly 320 may be made of a polymer material, such as polycarbonate (PC), acrylonitrile butadiene styrene (ABS) or a combination thereof.

As shown in FIG. 6, the panel assembly 110 can cover a side surface of the upper housing body 321A and be disposed above the lower housing body 321B. The panel assembly 110 may not cover the lower housing body 321B.

The height of the electromagnetic shielding assembly 330 in the longitudinal direction can be larger than the height of the electromagnetic shielding assembly 130 in the longitudinal direction. The electromagnetic shielding assembly 330 includes a body 331, a first elastic piece 332, a second elastic piece 333, an extended portion 334 and an elastic structure 335. The body 331 is disposed between the first elastic piece 332 and the second elastic piece 333. As shown in FIG. 8A, the first elastic piece 332 can be disposed on or connected to a first side 331-1 of the body 331; while the second elastic piece 333 can be disposed on or connected to a second side 331-2 of the body 331. The first side 331-1 of the body 331 is opposite to the second side 331-2 of the body 331. The first elastic piece 332 extends from the first side 331-1 of the body 331 toward the second elastic piece 333. The second elastic piece 333 extends from the second side 331-2 of the body 331 toward the first elastic piece 332. The first elastic piece 332 may not contact the second elastic piece 333. The body 331, the first elastic piece 332 and the second elastic piece 333 can define a space for accommodating the housing assembly 320. The first elastic piece 332 can cover a portion of the upper surface of the housing assembly 320 (as shown in FIG. 6). The second elastic piece 333 can cover a portion of the lower surface of the housing assembly 320 (as shown in FIG. 7). The body 331 may cover or contact a side surface of the upper housing body 321A and a side surface of the lower housing body 321B. The extended portion 334 can be connected to the body 331 (as shown in FIG. 8A). The extended portion 334 can extend from a side of the body 331 toward the outside of the support device 300. In the present embodiment, the extended portion 334 has an L-shaped bending structure, but the present disclosure is not limited thereto. The elastic structure 335 is disposed on the extended portion 334. In the present embodiment, the elastic structure 335 can be disposed on an arm of the L-shaped bending structure of the extended portion 334. The elastic structure 335 may have a curved structure and protrude toward the outside of the support device 300. When the support device 300 is installed in the cage, the elastic structure 335 can be positioned in a corresponding accommodating hole of the cage to increase the connection stability between the support device 300 and the cage. The electromagnetic shielding assembly 330 may be made of a conductive material, such as SUS301 stainless steel. In an embodiment, the elastic structure 335 can contact the cage for electrostatic discharge, which can improve the electrostatic protection capability of the support device 300.

The height of the bracket assembly 340 in the longitudinal direction can be larger than the height of the bracket assembly 140 in the longitudinal direction. The bracket assembly 340 includes a bracket body 341, bracket through holes 342, first connection holes 343, openings 345, first snap holes 346, side openings 347 and extension structures 348. The first snap holes 346 can be disposed on opposite sides of the bracket body 341. The first snap holes 346 can be disposed on and penetrate the upper surface of the bracket body 341. The bracket through holes 342 can be disposed on opposite sides of the bracket body 341. The bracket through holes 342 can penetrate the lower surface of the bracket body 341 (as shown in FIG. 8B). The extension structures 348 can be separated from each other. The extension structures 348 can be disposed on the edge of the lower surface of the bracket body 341 and extend toward the electromagnetic shielding assembly 330 and the housing assembly 320. The first connection hole 343 and the side opening 347 can penetrate the extension structure 348. In the present embodiment, the extension structure 348 has an L-shaped bending structure, the first connection hole 343 can penetrate one arm of the L-shaped bending structure of the extension structure 348, and the side opening 347 can penetrate the other arm of the L-shaped bending structure of the extension structure 348. The openings 345 can be disposed on opposite sides of the bracket body 341. As shown in FIG. 8A, the openings 345 can penetrate a side surface of the bracket body 341, and the side surface is connected between the upper surface and the lower surface of the bracket body 341. The first snap portion 328 of the housing assembly 320 can be engaged with the first snap hole 346 of the bracket assembly 340. The housing bulge part 327 of the housing assembly 320 can pass through the opening 345 of the bracket assembly 340, as shown in FIG. 6. The housing pillars 329 can pass through the side openings 347 of the bracket assembly 340, as shown in FIG. 7. The housing assembly 320 can be attached or fixed to the bracket assembly 340 through the first snap portion 328 and/or the housing bulge parts 327 and/or the housing pillars 329. A portion of the extended portion 334 of the electromagnetic shielding assembly 330 can be disposed in the bracket assembly 340, and the elastic structure 335 can pass through the bracket assembly 340 from a side surface of the bracket assembly 340 and protrude from the side surface of the bracket assembly 340, as shown in FIG. 8A. The bracket assembly 340 may be made of a metal material, such as SGCC steel.

The support device 300 may further include positioning pins 362. The length of the positioning pin 362 in the longitudinal direction can be larger than the length of the positioning pin 162 in the longitudinal direction. At least a portion of the extension structure 348 is disposed in the lower housing body 321B of the housing assembly 320 so that the first connection hole 343 overlaps the housing through hole 323 of the housing assembly 320. At least a portion of the button bulge part 1112 is disposed in the upper housing body 321A of the housing assembly 320 so that the button hole 1113 overlaps one of the housing through holes 323 of the housing assembly 320. At least a portion of the handle bulge part 1132 is disposed in the channel 326 of the housing assembly 320 so that the handle hole 1133 overlaps another one of the housing through holes 323 of the housing assembly 320. One of the positioning pins 362 can pass through the button hole 1113, the housing through hole 323 and the first connection hole 343 which overlap with each other, such that the button 111 can be pivotally connected to the housing assembly 320 through this positioning pin 362, and the button 111 can rotate relative to the housing assembly 320 with this positioning pin 362 as a rotation axis. Another one of the positioning pins 362 can pass through the handle hole 1133, the housing through holes 323 and the first connection hole 343 which overlap with each other, such that the handle 113 can be pivotally connected to the housing assembly 320 through this positioning pin 362, and the handle 113 can rotate relative to the housing assembly 320 with this positioning pin 362 as a rotation axis. The housing assembly 320 can be attached to the bracket assembly 340 through the positioning pins 362.

A portion of the first elastic element 160 of the support device 300 is disposed in the channel 326 of the housing assembly 320, and another portion of the first elastic element 160 is outside the channel 326 and protrudes from a side surface of the support device 300 (as shown in FIG. 9). The first elastic element 160 and the handle hook part 1134 can protrude from the same side surface of the support device 300. The first elastic element 160 is sleeved on the positioning pin 362 passing through the handle hole 1133. A portion of the second elastic element 164 of the support device 300 is disposed in the recess 324 of the housing assembly 320, and another portion of the second elastic element 164 passes through the extended portion 334 of the electromagnetic shielding assembly 330 and is disposed in the bracket assembly 340 (as shown in FIG. 9). The buffer 168 of the support device 300 is disposed in the bracket assembly 340. As shown in FIG. 9, a portion of the latch 166 of the support device 300 is disposed in the housing assembly 320, and another portion of the latch 166 passes through the electromagnetic shielding assembly 330 and is disposed in the buffer 168. As shown in FIG. 9, the first pillars 1662 and the connection portion 1661 of the latch 166 are disposed in the housing assembly 320, and a surface (e.g. second surface) of the latch 166 can contact or abut the body 331 of the electromagnetic shielding assembly 330, and the second pillars 1663 of the latch 166 pass through the electromagnetic shielding assembly 330 and are disposed in the buffer 168. The second pillar 1663 of the latch 166 can be disposed in the through hole 1681 of the buffer 168.

The bracket assembly 340 of the support device 300 is disposed between the tray assembly 150 and the electromagnetic shielding assembly 330. The bracket assembly 340 can be disposed above the bottom plate 152, and the bracket through hole 342 of the bracket assembly 340 can overlap the second connection hole 154, so the first fastener 172 can pass through the bracket through hole 342 and the second connection hole 154 which overlap with each other, and thus the tray assembly 150 can be fastened to the bracket assembly 340 through the first fastener 172.

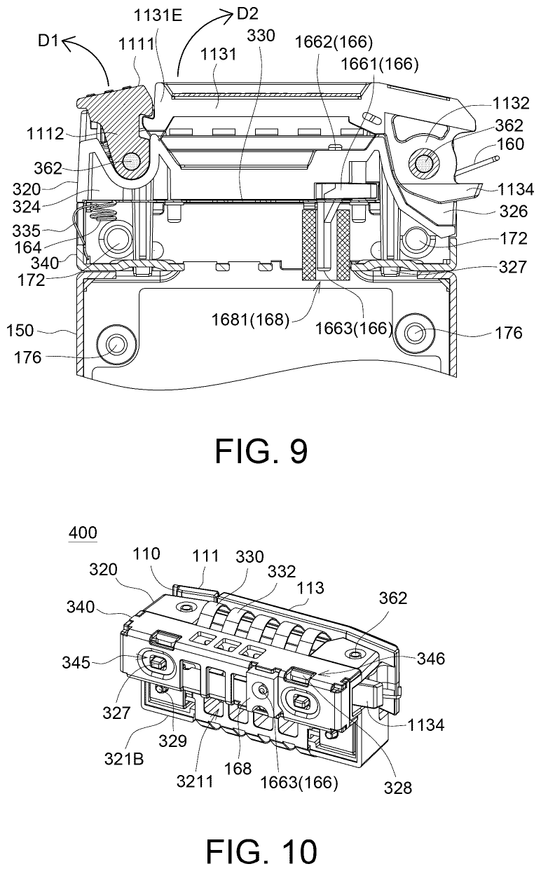

Referring to FIG. 10, FIG. 10 illustrates a schematic view of a support device 400 according to the fourth embodiment of the present disclosure. The difference between the support device 400 and the support device 300 shown in FIG. 6 to FIG. 9 is that, the support device 400 does not include the tray assembly 150. The support device 400 can be used to mount the electronic equipment having a tray (not shown), and the electronic equipment having a tray can be, for example, a server or a data storage device. The data storage device can be a hard disk drive (HDD) or a solid-state drive (SSD). The support device 400 can be fastened to the tray of the electronic equipment, and the support device 400 can be detachably installed in the cage (not shown), thus the electronic equipment together with the support device 400 can be detachably installed in the cage.

The size of the support device of the present disclosure can be set according to the common cage/rack design guidelines in the industry, and the size of the support device of the present disclosure can be adjusted according to the size of the electronic equipment to be mounted. The support devices of the present disclosure can be adapted for electronic equipment with different form factors. For example, the support devices 100 and 200 can be adapted for E1.S 9.5 mm solid-state drives based on EDSFF, and the support devices 300 and 400 can be adapted for E1.S 15 mm solid-state drives based on EDSFF; the present disclosure is not limited thereto.

As compared with the conventional support device, the support devices of the present disclosure include a low number of elements and do not use elements with complex structures that are difficult to assemble automatically. Therefore, the manufacturing cost of the support devices of the present disclosure can be decreased, and the support devices of the present disclosure are suitable for automated assembly.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A support device for mounting electronic equipment, comprising:
a panel assembly;
an electromagnetic shielding assembly;
a housing assembly disposed between the panel assembly and the electromagnetic shielding assembly; and
a bracket assembly,
wherein the electromagnetic shielding assembly is disposed between the housing assembly and the bracket assembly, and the bracket assembly comprises an extension structure extending toward the housing assembly and at least partially disposed within the housing assembly.

2. The support device according to claim 1, further comprising a tray assembly comprising an accommodation space for accommodating the electronic equipment, wherein the bracket assembly is disposed between the tray assembly and the electromagnetic shielding assembly.

3. The support device according to claim 1, further comprising a latch and a buffer, wherein a portion of the latch is disposed in the housing assembly, another portion of the latch passes through the electromagnetic shielding assembly and is disposed in the buffer, and the buffer is disposed in the bracket assembly.

4. The support device according to claim 1, further comprising a latch and a buffer, wherein the latch comprises a first pillar, a second pillar and a connection portion between the first pillar and the second pillar, the first pillar and the second pillar extend toward different directions, the first pillar and the connection portion are disposed in the housing assembly, the second pillar passes through the electromagnetic shielding assembly and is disposed in the buffer, and the buffer is disposed in the bracket assembly.

5. The support device according to claim 4, wherein the buffer comprises a through hole, and the second pillar is disposed in the through hole of the buffer.

6. The support device according to claim 1, wherein the electromagnetic shielding assembly comprises a first elastic piece, a second elastic piece and a body between the first elastic piece and the second elastic piece, the first elastic piece extends toward the second elastic piece and covers a first surface of the housing assembly, and the second elastic piece extends toward the first elastic piece and covers a second surface of the housing assembly.

7. The support device according to claim 6, wherein the electromagnetic shielding assembly comprises an extended portion and an elastic structure, the extended portion is connected to the body, the elastic structure is disposed on the extended portion, the elastic structure passes through the bracket assembly from a side surface of the bracket assembly and protrudes from the side surface of the bracket assembly.

8. The support device according to claim 7, wherein a portion of the extended portion is disposed within the bracket assembly.

9. The support device according to claim 1, wherein the panel assembly comprises a button and a handle, the button abuts the handle, the button and the handle are pivotally connected to the housing assembly through positioning pins respectively.

10. The support device according to claim 9, wherein the button rotates relative to the housing assembly to release the button from the handle.

11. The support device according to claim 9, wherein the handle comprises a handle body, a handle bulge part and a handle hook part, the handle bulge part protrudes from a surface of the handle body, the handle hook part is disposed on the handle bulge part and extends toward the outside of the support device, a portion of the handle hook part protrudes from a side surface of the support device, and the surface of the handle body faces the housing assembly.

12. The support device according to claim 11, further comprising a first elastic element and a second elastic element, wherein the first elastic element is sleeved on one of the positioning pins, a portion of the first elastic element protrudes from the side surface of the support device, and a portion of the second elastic element passes through the electromagnetic shielding assembly and is disposed in the bracket assembly.

13. The support device according to claim 12, wherein the housing assembly comprises a housing body, housing through holes penetrating the housing body, a recess disposed in the housing body, and a channel disposed in the housing body, the recess has an opening toward the electromagnetic shielding assembly, the channel has an opening toward the panel assembly and the outside of the support device, the channel communicates with one of the housing through holes, the channel accommodates at least a portion of the handle bulge part and a portion of the handle hook part, the first elastic element is disposed on one side of the handle bulge part, another portion of the first elastic element is disposed in the channel, and another portion of the second elastic element is disposed in the recess.

14. The support device according to claim 13, wherein the handle comprises a handle hole penetrating the handle bulge part, the button comprises a button body, a button bulge part protruding from a surface of the button body, and a button hole penetrating the button bulge part, the handle hole overlaps one of the housing through holes, and the button hole overlaps another one of the housing through holes.

15. The support device according to claim 12, wherein the first elastic element is a torsion spring.

16. The support device according to claim 10, wherein the button comprises a button body, a button bulge part protruding from a surface of the button body, and a button hole penetrating the button bulge part, at least a portion of the button bulge part is disposed in the housing assembly, the button abuts a handle movable end of the handle, the movable end of the handle is separated from the housing assembly when the button rotates relative to the housing assembly to release the button from the handle.

17. The support device according to claim 1, wherein the housing assembly comprises at least one first snap portion and a second snap portion, the bracket assembly comprises a first snap hole disposed on a first surface of the bracket assembly, and a second snap hole disposed on a second surface of the bracket assembly, the first snap portion of the housing assembly is engaged with the first snap hole of the bracket assembly, the second snap portion of the housing assembly passes through the electromagnetic shielding assembly and is engaged with the second snap hole of the bracket assembly.

18. The support device according to claim 17, wherein the number of the first snap portions is plural, and the second snap portion is disposed between the first snap portions.

19. The support device according to claim 17, wherein the housing assembly comprises a housing body and housing bulge parts, the housing bulge parts are disposed on the housing body and extend toward the electromagnetic shielding assembly, the first snap portion is disposed close to a first surface of the housing body, the second snap portion is disposed close to a second surface of the housing body and disposed between the housing bulge parts.

20. The support device according to claim 1, wherein the housing assembly comprises a first housing body and a second housing body disposed on one side of the first housing body, the panel assembly covers a side surface of the first housing body and is disposed above the second housing body.

21. The support device according to claim 20, wherein the housing assembly comprises housing through holes penetrating the first housing body and the second housing body, a recess disposed on the first housing body, a channel within the first housing body, housing bulge parts disposed on opposite sides of the first housing body, housing pillars disposed on opposite sides of the second housing body, and vent holes penetrating the second housing body, the recess has an opening toward the electromagnetic shielding assembly, the channel has an opening toward the panel assembly and the outside of the support device, the housing bulge parts extend toward the electromagnetic shielding assembly, and the housing pillars extend toward the electromagnetic shielding assembly.

22. The support device according to claim 21, wherein the panel assembly comprises a button and a handle, the button abuts the handle, each of the button and the handle is pivotally connected to the housing assembly through a positioning pin, the handle comprises a handle body, a handle bulge part protruding from a surface of the handle body, a handle hole penetrating the handle bulge part, and a handle hook part disposed on the handle bulge part, and the channel accommodates at least a portion of the handle bulge part and at least a portion of the handle hook part.

23. The support device according to claim 20, wherein the housing assembly comprises a snap portion disposed on the first housing body, the bracket assembly comprises a snap hole disposed on a first surface of the bracket assembly, the snap portion of the housing assembly is engaged with the snap hole of the bracket assembly, and the snap portion extends toward the electromagnetic shielding assembly.

24. The support device according to claim 23, further comprising a tray assembly comprising an accommodation space for accommodating the electronic equipment, wherein the bracket assembly is disposed between the tray assembly and the electromagnetic shielding assembly.

25. The support device according to claim 24, further comprising a latch and a buffer, wherein a portion of the latch is disposed in the housing assembly, another portion of the latch passes through the electromagnetic shielding assembly and is disposed in the buffer, and the buffer is disposed in the bracket assembly.

26. The support device according to claim 1, wherein the bracket assembly comprises a bracket body, a bracket through hole, a connection hole, an opening, and a first snap hole, the first snap hole penetrates a first surface of the bracket body, the bracket through hole penetrates a second surface of the bracket body, the connection hole penetrates the extension structure, the opening penetrates a side surface of the bracket body, and the side surface is connected between the first surface and the second surface.

27. The support device according to claim 26, wherein the bracket assembly comprises a second snap hole penetrating the second surface of the bracket body.

28. The support device according to claim 27, wherein the extension structure is disposed on the edge of the second surface of the bracket body, the housing assembly comprises a first snap portion and a second snap portion, the first snap portion of the housing assembly is engaged with the first snap hole of the bracket assembly, and the second snap portion of the housing assembly passes through the electromagnetic shielding assembly and is engaged with the second snap hole of the bracket assembly.

29. The support device according to claim 26, wherein the housing assembly comprises a housing body and a housing bulge part disposed on the housing body and extending toward the electromagnetic shielding assembly, and the housing bulge part passes through the opening of the bracket assembly.

30. The support device according to claim 26, wherein the housing assembly comprises a housing body and a housing through hole penetrating the housing body, and the connection hole of the bracket assembly overlaps the housing through hole of the housing assembly.

31. The support device according to claim 1, further comprising positioning pins, and the housing assembly is attached to the bracket assembly through the positioning pins.
